(19) United States
(12) Patent Application Publication
(10) Pub. No.: US 2014/0028315 A1
(43) Pub. Date: Jan. 30, 2014

(54) METHOD AND APPARATUS TO GENERATE A COMPLETE MAGNETIC RESONANCE IMAGE DATA SET TO BE DISPLAYED

(71) Applicant: Dominik Paul, Bubenreuth (DE)

(72) Inventor: Dominik Paul, Bubenreuth (DE)

(21) Appl. No.: 13/951,522

(22) Filed: Jul. 26, 2013

(30) Foreign Application Priority Data
Jul. 27, 2012 (DE) 102012213282.1

(51) Int. Cl. G01R 33/48

(52) U.S. Cl. CPC G01R 33/4828
USPC 324/309; 324/322; 382/131

(57) ABSTRACT

In a method, device and magnetic resonance system to generate a complete image data set to be displayed using a Dixon technique that separates at least two material types (in particular water and/or fat) in magnetic resonance data, after the determination of a first image data set associated with the first material type and the determination of a second image data set associated with the second material type, the first and second image data sets are combined to form a complete image data set depending on at least one weighting parameter.

### BACKGROUND OF THE INVENTION

1. Field of the Invention

The invention concerns a method to generate a complete magnetic resonance image data set to be displayed with the use of a Dixon technique separating at least two material types (in particular water and/or fat) in the acquired magnetic resonance data. The invention also concerns a device a magnetic resonance apparatus to implement such a method.

2. Description of the Prior Art

In magnetic resonance imaging, different techniques are known in order to acquire data for images that, for example, clearly show only protons in water as a first material type and mask out fat as a second material type. In particular, the “chemical shift selective fat saturation” (CHESS) sequence—in which the high signal of fat is suppressed in order to increase the diagnostic value and the reliability of an image data set to be obtained—is known and clinically used. The basic idea of the fat saturation (in CHESS) is to radiate in advance a pulse that acts only on the fat spins, which ensures that these are saturated and are no longer affected by the actual excitation pulse. Because the resonance frequencies of fat and water lie close to one another, a disadvantage of this method is its sensitivity with regard to the homogeneity of the basic magnetic field.

For CHESS sequences it is known that a user can choose between different fat saturation modes, for example a strong fat saturation and a weak fat saturation. This is based on the fact that the interpretation of image data sets occurs in an ultimately subjective manner, and different observers (different radiologists) have different biases. Some observers of magnetic resonance image data sets prefer to be able to also see a residual fat signal in a water image data set instead of a low fat signal, in order to be able to better differentiate between air (background) and lipid tissue. This is particularly the case in MSK (musculoskeletal) imaging, but also in other applications. However, there also exist fields in which the complete absence of a fat signal is preferred by radiologists.

In addition to the fat saturation (CHESS) that is routinely used in clinical practice, the Dixon technique is known as an additional method. The basic idea of the Dixon technique is to acquire (at least) two images with respectively different echo times and to produce a separation of fat and water using the phase development. However, because basic field inhomogeneities can typically be present, a number of Dixon techniques are known in which different phase errors of the images can be corrected. Dixon techniques are also known in which a complete analysis of the phase response takes place to determine a first image data set that shows the water signal as well as a second image data set that shows the fat signal. The Dixon technique can also be applied to other material types.

A frequently mentioned advantage of the Dixon technique is that only an extremely low residual fat signal remains in the water image data set. As noted above, however, a higher remaining fat signal than is normally advantageous is detected for the diagnostic interpretation of certain image data sets. In this case, the poorly perceptible appearance of the fat signal in Dixon water image data sets can sometimes be a disadvantage. In contrast to techniques for fat saturation, however, in the Dixon technique a commitment must be made for the particular examination being implemented as to whether the fat signal should be visible.

### SUMMARY OF THE INVENTION

An object of the invention is to enable the generation of special complete image data sets exhibiting a higher proportion of signals of other material types, even in the use of the Dixon technique.

This object is achieved in accordance with the invention in a method of the aforementioned type wherein, according to the invention, after the determination of a first image data set associated with the first material type and a second image data set associated with the second material type, the first and second image data sets are combined into a complete image data set depending on at least one weighting parameter.

Because the Dixon technique supplies a first image data set and a second image data set that are respectively associated with different material types, the special images (for example images that can be sensitive to a fat saturation technique) result from a combination of the first and second image data sets in accordance with the invention. In this way a complete image data set is created that includes signal influences from both material classes, and these signal influences can be controlled via the parameters. In this way, complete image data sets that sets are primarily associated with the first material type, for example water, that include an individually adapted residual fat signal can be generated, for example using the Dixon technique. A new contrast can also be achieved by the combination (scaled via the parameters) of the first and second Dixon image data sets. When water is the first material type and fat is the second material type, as is frequently the case, it is thus possible to generate water image data sets with a fat signal adapted (via the at least one parameter) in terms of its strength just as well as fat image data sets with a residual water signal.

In this way it is possible to generate the final, actual complete image data set (that is to be diagnostically evaluated) so that this image data set can be adapted to the specific evaluation task and/or the individual preference of the evaluating person. In this way, the diagnostic value of the complete image data set is increased and the reliability of the evaluation is improved. The expectations of a user—which frequently have to do with fat saturation techniques—can be better fulfilled, for example by signal portions of one material type that correspond to the fat saturation techniques being inserted into complete image data sets that are predominantly associated with the other material type.

As noted above, in many cases the first material type is water and/or the second material type is fat. However, other materials are also conceivable that can be differentiated via a Dixon technique, for example silicon and water.

In an embodiment of the present invention, a linear combination of the first and second image data sets to form the complete image data set takes place. It has been shown that a linear combination of the image data sets, ultimately a pixel-by-pixel addition or subtraction of the image data, supplies excellent, clear results with which images can be reproduced using fat saturation techniques. Instead of the general formulation—which assumes an arbitrary function

I_{g}=f(I_{w}, I_{f}, A, B),

wherein I_{g} represents the image data of the complete image data set, I_{w} and I_{f} represents the image data of the first and second image data sets, and A and B represent the parameters—a linear combination

I_{g}=A×I_{w}+B×I_{f}

thus results in the present case.

If it is desired to use one of the material types as a “primary type” for the complete image data set, it can be appropriate to set the associated parameters (thus the coefficients A) to 1 so that the first image data set is weighted with a parameter value of 1 in the linear combination, and the second image data set is weighted with a second parameter deviating from 1. This second parameter is then in particular less than 1, and can lie between 0 and 0.6, for example. In this way, an image data set associated with the first material class can be generated as a complete image data set, which image data set has a variable signal of the second material class. For example, it is thus possible to realize a complete water image data set with a variable fat signal.

It can also be appropriate for at least one parameter of the linear combination to be negatively selected. In this way, it is possible to nevertheless generate a complete image data set even when the first image data set and the second image data set still have residual signals of the respective other material class, which complete image data set is completely free of signals of one material class (frequently also designated as a “black signal”). This occurs by one of the image data set being subtracted from the other, and it is then preferred that negative image values of the complete image data set (which negative values arise within the scope of the linear combination) are treated as an image value of zero. In a simple embodiment, in the indicated linear combination the parameter A can be set to 1 but the parameter B can be set to −1. It then results that

I_{g}=I_{w}−I_{f}.

If all values that lie below 0 are now set to 0, an image results that is completely free of the signals of the second material class—in one example, a complete water image data set with a “black [dark]” fat signal.

Overall, within the scope of the present invention it is possible to also reproduce known fat saturation techniques—thus to provide linear combinations or, respectively, specific parameter values for the parameters B—so that, ultimately, a strong fat saturation and a weak fat saturation can be “simulated” in order to satisfy corresponding expectations of the user.

Within the scope of the present invention, multiple hard-set parameters or parameters sets—in particular parameter or parameter sets associated with different evaluation questions—are stored (in a memory device, for example) that are retrieved depending on a current evaluation task and used to generate the complete image data set. In this case, predefined parameters or parameter sets are thus provided for specific questions, which predefined parameters or parameter sets are retrieved automatically and lead to the generation of a suitable complete image data set.

In an embodiment of the present invention may be provided (possibly additionally) that an operating element for the adjustment of at least one parameter is displayed. This means that a user can have influence on the at least one parameter and generate corresponding complete image data sets. It is preferred for the operating element to be displayed simultaneously with the complete image data set, and an immediate new determination and display of the complete image data set takes place (such as in real time) upon a variation of the at least one adjustable parameter. A dynamic parameter adaptation is realized in this way, with the operating element being (for example) a slider or the like, in particular a part of a user interface. The user can adapt the at least one parameter and observe the effects on the complete image data set in real time, so the complete image data set can be re-determined quickly after every calculation. An image of the complete image data set can be found in an extremely simple and intuitive manner, this image corresponding to the requirements of the user (in particular a person making diagnosis).

In addition to the method, the invention concerns a device to generate and display a complete image data set given the use of a Dixon technique that separates at least two material types (in particular water and/or fat) in magnetic resonance data, having a combination unit to combine a first image data set (associated with the first material type) and a second image data set (associated with the second material type) into a complete image data set depending on at least one weighting parameter; and a display device to present the complete image data set. The device according to the invention is consequently designed to implement the method according to the invention. It can in particular be a calculation device. All embodiments of the method according to the invention can analogously be transferred to the device according to the invention, with the advantages that have already been cited.

The device according to the invention can also include an input device for the at least one parameter, allowing the parameter to be adaptable by a user.

The present invention also concerns a magnetic resonance apparatus that has a device according to the invention. The calculation device according to the invention can thus be integrated into a magnetic resonance apparatus, for example, so as to be used as well to implement the method according to the invention, without existing hardware and/or software components having to be supplemented with suitable components for implementation of the method according to the invention. Magnetic resonance devices already frequently have display and input devices that can be used to display the complete image data set and for the optionally provided input of the at least one parameter. Calculation components—for example in the form of an image computer—for magnetic resonance devices are also known.

### BRIEF DESCRIPTION OF THE DRAWINGS

FIG. 1 is a flowchart of an exemplary embodiment of the method according to the invention.

FIG. 2 shows the effect of the method according to the invention in a first parameter selection.

FIG. 3 shows the effect of the method according to the invention in a second parameter selection.

FIG. 4 schematically illustrates a magnetic resonance device according to the invention.

### DESCRIPTION OF THE PREFERRED EMBODIMENTS

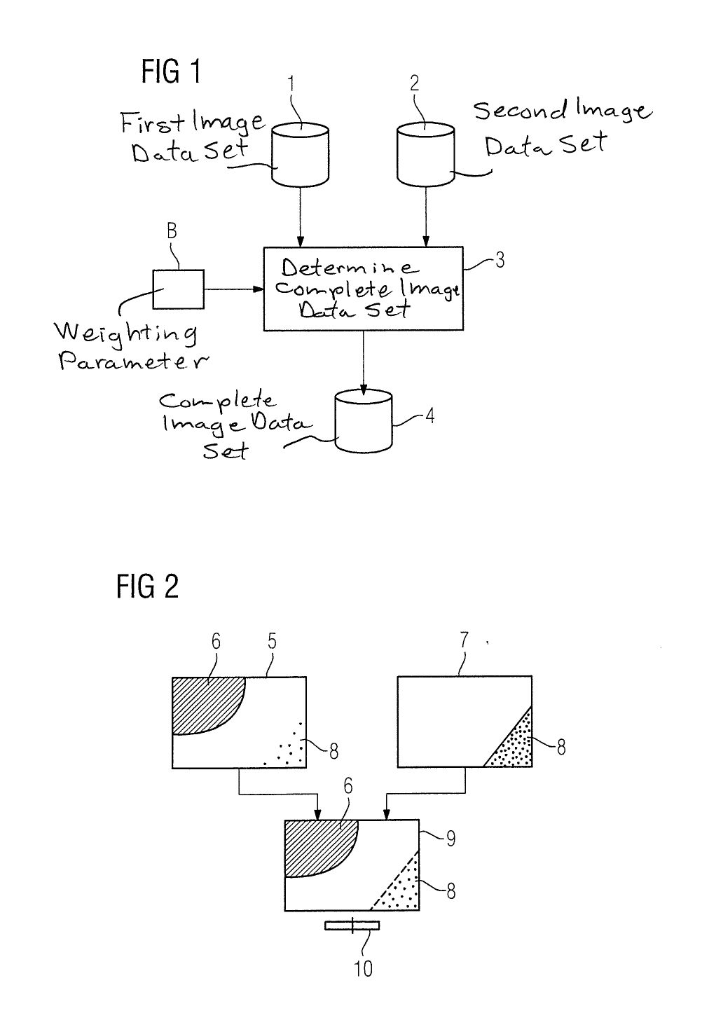

FIG. 1 shows a flowchart of an exemplary embodiment of the method according to the invention. Here a Dixon technique is assumed with which water and fat (as material classes) can be separated, which means that the first image data set resulting from the application of the Dixon technique is a water image data set [and] the second image data set resulting from the Dixon technique is a fat image data set.

FIG. 1 shows the first image data set 1 and the second image data set 2 as input data for the method according to the invention. As has been described, both are associated with corresponding material classes—here fat and water. In Step 3, a complete data set 4 that is to be displayed for evaluation is determined in that a linear combination of the first image data set 1 and the second image data set 2 is conducted. In the exemplary embodiment, it is assumed that an image centered on water as a material class should be generated so that the first image data set is always weighted with 1 in the first image data set; the second image data set 2 is weighted with a parameter B that is less than 1.

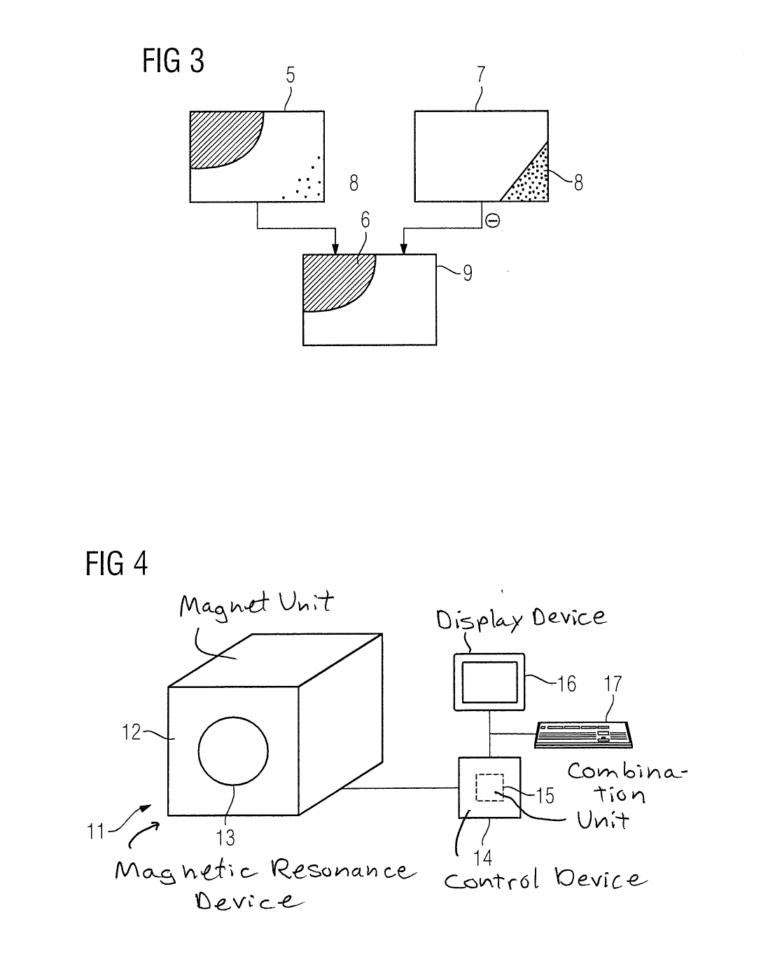

In this way a complete water image data set 4 can be generated in which the proportion of remaining fat signals can be arbitrarily adjusted using the parameter B, as should be explained in an example in FIGS. 2 and 3, which show abstract sections from the first image data set 1, the second image data set 2 and the complete image data set 4 for exemplary cases.

The section 5 of the first image data set 1 clearly includes a region 6 in which a water signal has been measured. The section 7 of the second image data set 2 includes a region 8 in which a fat signal has been measured. While the fat signal is also to be weakly detected in the first image data set 1 (as is clear in region 8), in the second image data set 2 the water signal is not to be detected here, although this is necessarily also possible.

If the user would now like an image that corresponds to a weaker fat saturation, or if such an image is more suitable for the special evaluation task, he can now more clearly emphasize the fat signal in the complete image data set 4 (represented by the section 9), for example in that the parameter B is selected in a range from 0.4 to 0.6. Furthermore, the water signal is accordingly clearly apparent in region 6 in section 9; however, the fat signal in region 8 is brighter.

FIG. 3 shows an additional variant in which the parameter B was chosen as—1, which means that the second image data set 2 is subtracted from the first image data set 1. Negative image values that arise are thereby interpreted as an image value 0. As the image section 9 in turn shows, the result is a pure, complete water image data set in which no fat signals whatsoever are consequently contained anymore, which means that even the fat signals that are still visible in section 5 in region 8 in the first image data set 1 have been removed.

Depending on the parameter selection, different possibilities clearly exist for the generation of complete image data sets 4 that can then be presented at a corresponding display device.

In this exemplary embodiment, it is also possible for a user to adjust the parameter B (or, respectively, to also adjust a parameter A determining the scaling of the water signal when this provided) via a corresponding operating element. In FIG. 2, as an example a controller 10 for the parameter B is shown as an operating element below section 9, which controller 10 is simultaneously shown with the complete image data set 4. If the parameter value is varied by means of the controller 10, the complete image data set 4 is thus immediately recalculated in real time, and the changes are displayed. A dynamic adaptation of parameters is thus possible.

FIG. 4 shows a magnetic resonance device 11 according to the invention in the form of a principle drawing. In a known manner, this comprises a primary magnet unit 12 with a patient receptacle 13 where magnetic resonance data of a patient can be acquired; in particular, the first and second image data set 1, 2 can also be measured by means of the Dixon technique. The operation of the magnetic resonance device 11 is controlled by a control device 14 (consequently a calculation device) which presently also acts as a device according to the invention for the generation and display of the complete image data set 4. For this, a combination unit 15 is provided that can implement Step 3 (explained with regard to FIG. 1). The complete image data set 4 can then be presented at a display device 16. An input device 17 is also provided via which the controller 10 can be operated, for example.

Although modifications and changes may be suggested by those skilled in the art, it is the intention of the inventor to embody within the patent warranted hereon all changes and modifications as reasonably and properly come within the scope of his contribution to the art.

I claim as my invention:

1. A method to generate a complete magnetic resonance (MR) image data set, comprising:
operating an MR data acquisition unit according to a Dixon technique to acquire a first image data set associated with a first material type in an examination subject and to acquire a second image data set associated with a second, different material type in the examination subject;
supplying said first and second image data sets to a processor and, in said processor, automatically combining said first and second image data sets with each other, dependent on at least one weighting parameter applied to at least one of said first and second image data sets, to obtain a complete image data set; and
making said complete image data set available at an output of said processor in electronic form as a data file.

2. A method as claimed in claim 1 comprising acquiring said first image data set associated with water in said subject as said first material type, and acquiring said second image data set associated with fat or silicon in the examination subject, as said second material type.

3. A method as claimed in claim 1 comprising, in said processor, linearly combining said first and second image data sets to form said complete image data set, using said at least one weighting parameter.

4. A method as claimed in claim 3 comprising weighting said first image data set in said processor with a parameter value of one in said linear combination, and weighting said second image data set with a second parameter that deviates from one.

5. A method as claimed in claim 3 comprising employing at least one negative weighting parameter in said linear combination of said first and second image data sets.

6. A method as claimed in claim 5 comprising treating any negative image values in said image data set that arise due to the use of said at least one negative parameter, as having respective image values of zero.

7. A method as claimed in claim 1 comprising, via a user interface connected to said processor, displaying an operating element that allows user-selection of said at least one weighting parameter.

8. A method as claimed in claim 7 comprising displaying said operating element at said user interface simultaneously with said complete image data set in order to allow an intermediate review of said complete image data set, and comprising redetermining said complete image data set after entry of a reselected weighting parameter via said user interface.

9. A computerized system to generate a complete magnetic resonance (MR) image data set, comprising:
a processor having an input supplied with data acquired according to a Dixon technique, comprising a first image data set associated with a first material type in an examination subject and a second image data set associated with a second, different material type in the examination subject;
said processor being configured to automatically combine said first and second image data sets with each other, dependent on at least one weighting parameter applied to at least one of said first and second image data sets, to obtain a complete image data set; and
said processor being configured to make said complete image data set available at an output of said processor in electronic form as a data file.

10. A magnetic resonance (MR) apparatus comprising:
an MR data acquisition unit;
a control unit being configured to operate the MR data acquisition unit according to a Dixon technique to acquire a first image data set associated with a first material type in an examination subject and to acquire a second image data set associated with a second, different material type in the examination subject;
a processor supplied with said first and second image data sets, said processor being configured to automatically combine said first and second image data sets with each other, dependent on at least one weighting parameter applied to at least one of said first and second image data sets, to obtain a complete image data set; and
said processor being configured to make said complete image data set available at an output of said processor in electronic form as a data file.
